(19) United States
(12) Patent Application Publication
(10) Pub. No.: US 2026/0247658 A1
(43) Pub. Date: Aug. 20, 2026

(54) SHIELDED GATE TRENCH SEMICONDUCTOR DEVICE AND ITS MANUFACTURING METHOD

(71) Applicant: HEJIAN TECHNOLOGY (SUZHOU) CO., LTD., Suzhou Jiangsu Province Suzhou (CN)

(72) Inventors: Yuan cheng ZHENG, Suzhou Jiangsu Province Suzhou (CN); Xin huan SHI, Suzhou Jiangsu Province Suzhou (CN); Bo LIU, Suzhou Jiangsu Province Suzhou (CN); Dong hua WU, Suzhou Jiangsu Province Suzhou (CN); Yu sheng SHEN, Suzhou Jiangsu Province Suzhou (CN); Wei LI, Suzhou Jiangsu Province Suzhou (CN)

(73) Assignee: HEJIAN TECHNOLOGY (SUZHOU) CO., LTD., Suzhou Jiangsu Province Suzhou (CN)

(21) Appl. No.: 19/183,015

(22) Filed: Apr. 18, 2025

(30) Foreign Application Priority Data
Feb. 17, 2025 (CN) 202510171683.5

(51) Int. Cl. H10D 30/66; H10D 30/01; H10D 64/00; H10D 84/01

(52) U.S. Cl. CPC H10D 30/668; H10D 30/0297; H10D 64/117; H10D 84/013

(57) ABSTRACT

A shielded gate trench semiconductor device includes first and second shielded gate trench transistors. The second shielded gate trench transistor includes: an epitaxial layer disposed on a side of a base substrate; a body region disposed on a side of the epitaxial layer facing away from the base substrate; a first source region disposed on a side of the body region facing away from the base substrate; a groove penetrating the first source region and the body region, and extending into an inside of the epitaxial layer; a first oxide layer disposed on a sidewall of the groove and on the side of the first source region facing away from the base substrate; a gate electrode disposed to correspond to the first oxide layer and fills a portion of the groove; a first metal layer formed on a side of the first source region facing away from the base substrate.

### BACKGROUND

### Field of Technology

The present invention relates to the field of semiconductor technology, and in particular to a manufacturing method of a shielded gate trench semiconductor device specifically applicable to related products and processes such as logic components, mixed signal components, embedded memories, BCD (bipolar-complementary metal oxide semiconductor-double diffused metal oxide semiconductor), trench transistors (trench MOSFET) and high-voltage components (such as power management integrated circuits), etc.

### Description of the Related Art

Shielded gate trench semiconductor device (SGT MOSFET) is an advanced power semiconductor device. Due to its excellent performance and reliability, it is widely used in many fields (such as fields of new energy vehicles, photovoltaic new energy, industrial electronics, consumer electronics, smart manufacturing, 5G communications, and the Internet of Things, etc.).

The disadvantages of existing shielded gate trench semiconductor devices are large forward conducting voltage and high power consumption, making it difficult to meet usage requirements.

### SUMMARY

In light of this, the present invention provides a shielded gate trench semiconductor device and a manufacturing method thereof, which solves the problems of large forward conduction voltage and high power consumption of existing shielded gate trench semiconductor devices.

In one aspect, an embodiment of the present invention provides a shielded gate trench semiconductor device, comprising: a base substrate, and a first shielded gate trench transistor and a second shielded gate trench transistor formed thereon.

Wherein, the second shielded gate trench transistor includes: an epitaxial layer disposed on a side of the base substrate; a body region disposed on a side of the epitaxial layer facing away from the base substrate; a first source region disposed on a side of the body region facing away from the base substrate; a groove that penetrates the first source region and the body region, and extends into an inside of the epitaxial layer; a first oxide layer disposed on a sidewall of the groove and on the side of the first source region facing away from the base substrate, wherein a thickness of the first oxide layer is less than a thickness of an oxide layer of the first shielded gate trench transistor; a gate electrode disposed to correspond to the first oxide layer and fills a portion of the groove; and a first metal layer formed on a side of the first source region facing away from the base substrate, wherein the first metal layer is connected to the gate electrode, the first source region, the body region, and a source region of the first shielded gate trench transistor, respectively.

In some embodiments, a concentration of the first source region is greater than a concentration of the source region of the first shielded gate trench transistor.

In some embodiments, the thickness of the first oxide layer is 50 angstroms ± 10 angstroms.

In some embodiments, a doping type of the first source region is of a first doping type, a doping type of the body region is of a second doping type, and a doping concentration of the body region is less than a doping concentration of the first source region.

In some embodiments, the first metal layer is used to apply a first voltage to the gate electrode, the first source region, and the body region of the second shielded gate trench transistor and the source region of the first shielded gate trench transistor.

In some embodiments, the first shielded gate trench transistor includes: a second metal layer connected to a gate electrode of the first shielded gate trench transistor, wherein the second metal layer is used to apply a second voltage to the gate electrode of the first shielded gate trench transistor; and a third metal layer connected to the source region and a body region of the first shielded gate trench transistor, wherein the third metal layer is used to apply a third voltage to the source region and the body region of the first shielded gate trench transistor.

In another aspect, an embodiment of the present invention provides a manufacturing method of a shielded gate trench semiconductor device, the manufacturing method comprising: forming a first shielded gate trench transistor and a second shielded gate trench transistor on a base substrate.

Wherein the formation of the second shielded gate trench transistor includes: forming an epitaxial layer on a side of the base substrate; forming a groove in the epitaxial layer, wherein the groove extends from a side of the epitaxial layer facing away from the base substrate towards a direction closer to the base substrate; forming a first oxide layer on a sidewall of the groove and on the side of the epitaxial layer facing away from the base substrate, wherein a thickness of the first oxide layer is less than a thickness of an oxide layer of the first shielded gate trench transistor; forming a gate electrode that fills and covers a portion of the groove at a position corresponding to the first oxide layer; forming a body region on a side of the first oxide layer closer to the base substrate; forming a first source region on a side of the body region closer to the first oxide layer; forming a first metal layer on a side of the first oxide layer facing away from the base substrate, wherein the first metal layer is connected to the gate electrode, the first source region, the body region, and a source region of the first shielded gate trench transistor, respectively.

In some embodiments, the formation of the first source region on the side of the body region closer to the first oxide layer includes: forming a second source region on the side of the body region closer to the first oxide layer and forming the first source region based on the second source region, wherein a concentration of the first source region is greater than a concentration of the source region of the first shielded gate trench transistor.

In some embodiments, the formation of the second source region on the side of the body region closer to the first oxide layer and the formation of the first source region based on the second source region includes: forming the second source region on the side of the body region closer to the first oxide layer through photolithography and ion implantation processes; and forming the first source region based on the second source region through photolithography, ion implantation, and annealing processes.

In some embodiments, the formation of the first oxide layer on the sidewall of the groove and on the side of the epitaxial layer facing away from the base substrate includes: forming a second oxide layer inside the groove and on the side of the epitaxial layer facing away from the base substrate; removing the second oxide layer on the side of the epitaxial layer facing away from the base substrate and the second oxide layer on the sidewall of the groove facing away from the base substrate through photolithography and etching processes; and forming the first oxide layer at positions where the second oxide layer has been removed from the epitaxial layer and the sidewall of the groove, wherein a thickness of the first oxide layer is 50 angstroms ± 10 angstroms.

The present invention has at least the following beneficial effects.

The present invention provides a shielded gate trench semiconductor device and a manufacturing method thereof. The shielded gate trench semiconductor device provided by the present invention comprises: a base substrate, and a first shielded gate trench transistor and a second shielded gate trench transistor formed thereon, wherein, the second shielded gate trench transistor includes: an epitaxial layer disposed on a side of the base substrate; a body region disposed on a side of the epitaxial layer facing away from the base substrate; a first source region disposed on a side of the body region facing away from the base substrate; a groove that penetrates the first source region and the body region, and extends into an inside of the epitaxial layer; a first oxide layer disposed on a sidewall of the groove and on the side of the first source region facing away from the base substrate, wherein a thickness of the first oxide layer is less than a thickness of an oxide layer of the first shielded gate trench transistor; a gate electrode disposed to correspond to the first oxide layer and fills a portion of the groove; and a first metal layer formed on a side of the first source region facing away from the base substrate, wherein the first metal layer is connected to the gate electrode, the first source region, the body region, and a source region of the first shielded gate trench transistor, respectively. The shielded gate trench semiconductor device provided by the present invention has a low forward voltage drop and low power consumption.

The present invention is specifically applicable to related products and processes such as logic components, mixed signal components, embedded memories, BCD (bipolar-complementary metal oxide semiconductor-double diffused metal oxide semiconductor), trench transistors (trench MOSFET) and high-voltage components (such as power management integrated circuits), etc.

### BRIEF DESCRIPTION OF THE DRAWINGS

In order to more clearly illustrate the embodiments of the present invention or the technical solutions in the prior art, the following will briefly introduce the drawings needed to describe the embodiments or the prior art. Obviously, the drawings in the following description are only some embodiments of the present invention. To a person with ordinary skills in the art, other embodiments can be obtained based on these drawings without exerting creative efforts. In the drawings:

FIG. 1A is a schematic structural diagram of an exemplary shielded gate trench semiconductor device.

FIG. 1B is a schematic diagram of the manufacturing process of the shielded gate trench semiconductor device shown in FIG. 1A.

FIG. 2 is a schematic structural diagram of a shielded gate trench semiconductor device according to an embodiment of the present invention.

FIG. 3A is a schematic diagram of the manufacturing process of a second shielded gate trench transistor according to an embodiment of the present invention.

FIG. 3B is a schematic diagram of the manufacturing process of a first oxide layer of the second shielded gate trench transistor according to an embodiment of the present invention.

FIG. 4 is a schematic diagram of the manufacturing process of a first source region of the second shielded gate trench transistor according to an embodiment of the present invention.

### DETAILED DESCRIPTION

In order to make the purpose, technical solutions and advantages of the present invention more clear, the embodiments of the present invention will be further described in detail below with reference to specific embodiments and the accompanying drawings.

It should be noted that all expressions using “first” and “second” in the embodiments of the present invention are to distinguish two entities or non-identical parameters with the same name. It can be seen that “first” and “second” are only for convenience of expression and should not be understood as limiting the embodiments of the present invention. This will not be explained anymore in subsequent embodiments.

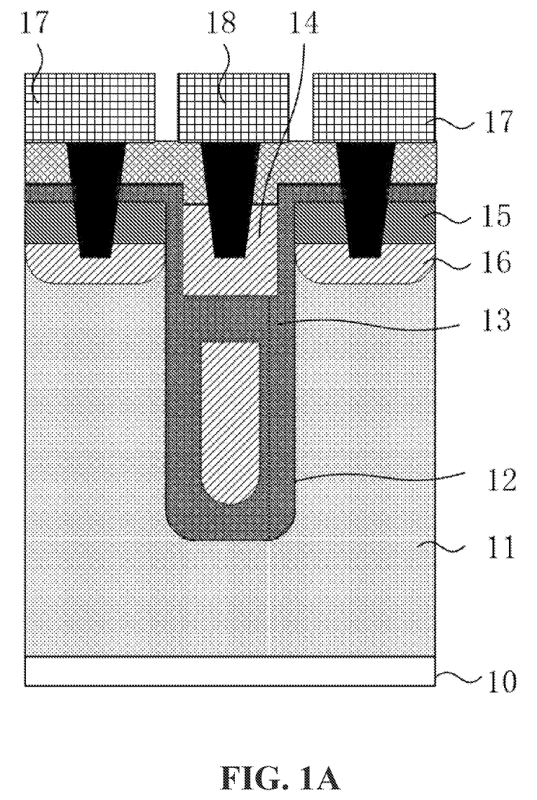

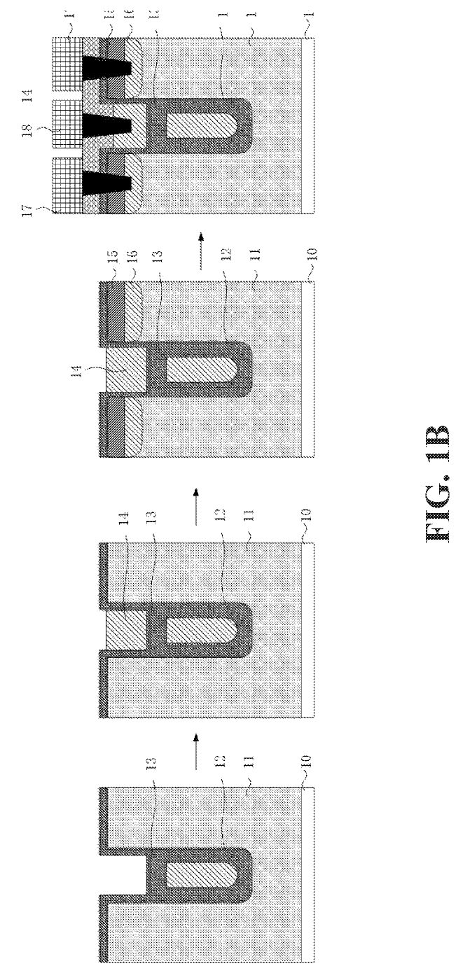

As shown in FIG. 1A, an exemplary shielded gate trench semiconductor device includes: a base substrate 10; an epitaxial layer 11 disposed on the base substrate; a groove 12 disposed in the epitaxial layer 11; an oxide layer 13 disposed in the groove 12 and on the side of the epitaxial layer 11 facing away from the base substrate 10; a gate electrode 14 disposed in the groove 12; a source region 15 and a body region 16 disposed between the oxide layer 13 and the epitaxial layer 11; a source metal layer 17 connected to the source region 15 and the body region 16; and a gate metal layer 18 connected to the gate electrode 14.

As shown in FIG. 1B, the manufacturing method of this exemplary shielded gate trench semiconductor device is: forming the base substrate 10, the epitaxial layer 11 and the groove 12, and forming the gate oxide layer (referred to as GOX) 13 on the epitaxial layer (referred to as EPI) 11 → forming a gate polysilicon layer → forming the body region 16 through ion implantation and tempering → forming the source region 15 through photolithography, ion implantation and tempering → forming an interlayer dielectric layer (Inter-Layer Dielectric, referred to as ILD) 19 → forming the source metal layer 17 and the gate metal layer 18, wherein the source metal layer 17 is connected to the body region 16, and the gate metal layer 18 is connected to the source region 15, thereby obtaining the shielded gate trench semiconductor device as shown in FIG. 1A.

The forward voltage drop of the shielded gate trench semiconductor device obtained by the above manufacturing method is 0.5V. This forward voltage drop is large, resulting in high power consumption of the shielded gate trench semiconductor device, which cannot meet the usage requirements.

In view of this, in order to solve at least one of the above technical problems, embodiments of the present invention provide a shielded gate trench semiconductor device and a manufacturing method thereof, which can reduce the forward voltage drop of the shielded gate trench semiconductor device, and, in conditions where the input current is identical, reduce the power consumption of the shielded gate trench semiconductor device. The present invention will be described in detail below with reference to the embodiments and drawings.

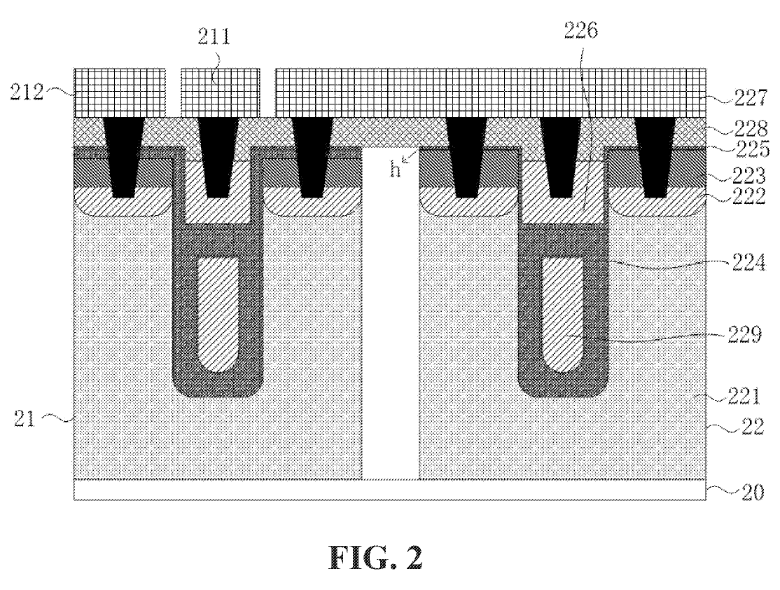

A first aspect of an embodiment of the present invention provides a shielded gate trench semiconductor device. As shown in FIG. 2, the shielded gate trench semiconductor device includes: a base substrate 20; and a first shielded gate trench transistor 21 and a second shielded gate trench transistor 22 formed on the base substrate 20. The second shielded gate trench transistor 22 includes: an epitaxial layer 221 disposed on a side of the base substrate 20; a body region 222 disposed on a side of the epitaxial layer 221 facing away from the base substrate 20; a first source region 223 disposed on a side of the body region 222 facing away from the base substrate 20; a groove 224 that penetrates the first source region 223 and the body region 222, and extends to the inside of the epitaxial layer 221; a first oxide layer 225 disposed on the sidewalls of the groove 224 and on a side of the first source region 223 facing away from the base substrate 20, wherein the thickness of the first oxide layer 225 is smaller than the thickness of the oxide layer of the first shielded gate trench transistor 21; a gate electrode 226 disposed to correspond to the first oxide layer 225 and fills and covers a portion of the groove 224; a first metal layer 227 disposed on a side of the first source region 223 facing away from the base substrate 20, wherein the first metal layer 227 is connected to the gate electrode 226, the first source region 223, the body region 222, and a source region of the first shielded gate trench transistor 21, respectively.

In the embodiment of the present invention, the structure of the first shielded gate trench transistor 21 is basically the same as the structure of the shielded gate trench semiconductor device shown in FIG. 1A, and will not be described again here.

The shielded gate trench semiconductor device according to the embodiment of the present invention can be applied in multiple fields, such as the fields of new energy vehicles, photovoltaic new energy, industrial electronics, consumer electronics, smart manufacturing, 5G communications, and the Internet of Things, etc.

The base substrate 20 may use silicon as a base material. For example, the base substrate may be a single crystal silicon base substrate or a doped silicon base substrate. The material of the epitaxial layer 221 may be polycrystalline silicon. The body region 222 and the first source region 223 may be doped N-type or P-type semiconductor materials. For example, boron-doped SiGe (P-type) or phosphorus-doped SiC (N-type), but not limited thereto. The material of the first oxide layer 225 may be an oxide, such as silicon oxide, but is not limited thereto. The material of the gate electrode 226 may be polycrystalline silicon. The material of the first metal layer 227 may be silver, copper, aluminum or other metal materials.

The working process of the shielded gate trench semiconductor device according to the embodiment of the present invention is: simultaneously applying a forward voltage to the first source region 223 and gate electrode 226 of the second shielded gate trench transistor 22 and the source region of the first shielded gate trench transistor 21, grounding the drain region (i.e., the epitaxial layer) of the second shielded gate trench transistor 22 and the drain region (i.e., the epitaxial layer) of the first shielded gate trench transistor 21. Since the thickness of the first oxide layer 225 of second shielded gate trench transistor 22 is smaller than the thickness of the oxide layer of the first shielded gate trench transistor 21, and the voltage applied to the first source region 223 and the gate electrode 226 of the second shielded gate trench transistor 22 is the same as that of the source region of the first shielded gate trench transistor 21, therefore, the on-resistance of the second shielded gate trench transistor 22 is reduced. The second shielded gate trench transistor 22 is turned on earlier than the first shielded gate trench transistor 21. Thus, the forward voltage drop of the shielded gate trench semiconductor device is reduced, and the power consumption is also reduced.

In some embodiments of the present invention, the thickness h of the first oxide layer of the second shielded gate trench transistor 22 as shown in FIG. 2 is 50 angstroms ± 10 angstroms. By controlling the thickness of the first oxide layer of the second shielded gate trench transistor 22 within the range of 50 angstroms ± 10 angstroms, the forward voltage drop of the shielded gate trench semiconductor device can be reduced by about 50%, which greatly reduces the forward voltage drop and power consumption of the shielded gate trench semiconductor device.

In some embodiments of the present invention, the concentration of the first source region 223 of the second shielded gate trench transistor 22 as shown in FIG. 2 is greater than the concentration of the source region of the first shielded gate trench transistor 21, thereby further reducing the forward voltage drop and power consumption of the shielded gate trench semiconductor device.

In some embodiments of the present invention, the doping type of the first source region 223 of the second shielded gate trench transistor 22 shown in FIG. 2 is the first doping type, and the doping type of the body region 222 is the second doping type.

Wherein, the doping concentration of the body region 222 is smaller than the doping concentration of the first source region 223.

In some examples, the first doping type may be N-type and the second doping type may be P-type. For example, an N-type semiconductor can be formed by doping with arsenic (As), and a P-type semiconductor can be formed by doping with boron (B).

In some embodiments of the present invention, the first metal layer 227 of the second shielded gate trench transistor 22 as shown in FIG. 2 is used to apply a first voltage to the gate electrode 226, the first source region 223 and the body region 222 of the second shielded gate trench transistor 22 and the source region of the first shielded gate trench transistor 21.

In some embodiments of the present invention, the first shielded gate trench transistor 21 as shown in FIG. 2 may include: a second metal layer 211 connected to the gate electrode of the first shielded gate trench transistor 21; and a third metal layer 212 connected to the source region and body region of the first shielded gate trench transistor 21.

The second metal layer 211 is used to apply a second voltage to the gate electrode of the first shielded gate trench transistor 21, and the third metal layer 212 is used to apply a third voltage to the source and body regions of the first shielded gate trench transistor 21.

In some examples, the range of the first voltage may be: (5±10%)V, the range of the second voltage may be 0V (i.e., ground), and the range of the third voltage may be: (5±10%)V.

In some embodiments of the present invention, the second shielded gate trench transistor 22 as shown in FIG. 2 further includes an interlayer dielectric layer 228 disposed on a side of the first metal layer 227 close to the base substrate 20.

In some embodiments of the present invention, the second shielded gate trench transistor 22 as shown in FIG. 2 further includes a field plate 229 disposed in the groove 224. The material of the field plate 229 may be polycrystalline silicon.

Based on the same inventive concept, according to another aspect of the present invention, in order to form a shielded gate trench semiconductor device as shown in FIG. 2, an embodiment of the present invention also provides a manufacturing method of a shielded gate trench semiconductor device, the method includes: forming a first shielded gate trench transistor and a second shielded gate trench transistor on a base substrate.

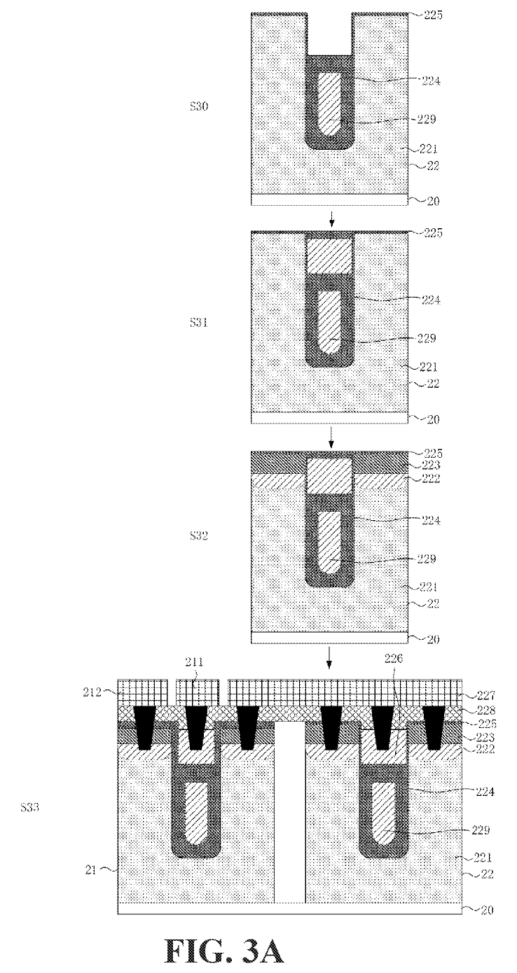

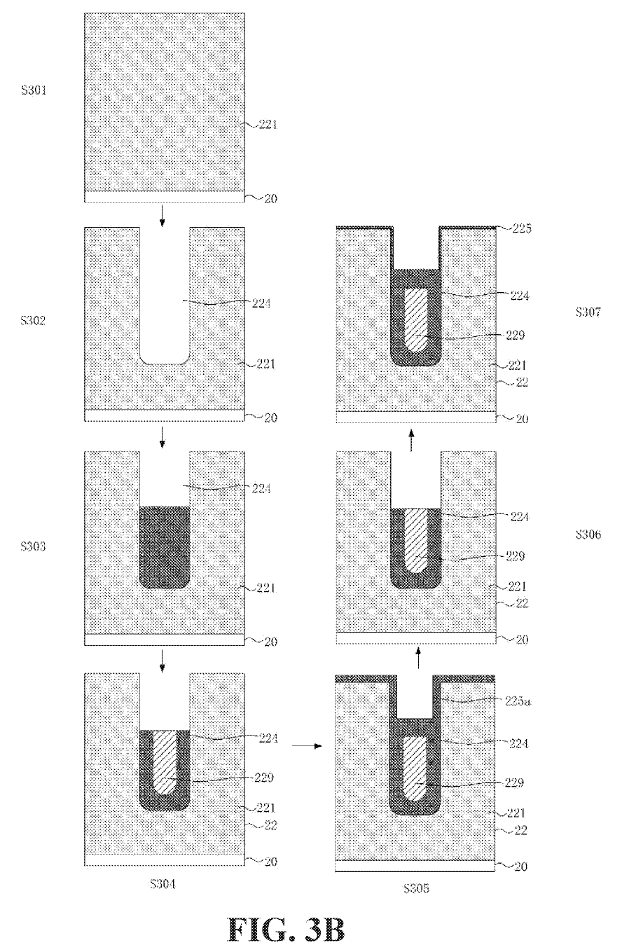

As shown in FIG. 3A, the method of forming the second shielded gate trench transistor includes steps S30-S33.

Step S30: forming the epitaxial layer 221 on a side of the base substrate 20, forming the groove 224 in the epitaxial layer 221, and forming the first oxide layer 225 on the side walls of the groove 224 and the side of the epitaxial layer 221 facing away from the base substrate 20.

Wherein, the groove 224 extends from the side of the epitaxial layer 221 facing away from the base substrate 20 toward a direction close to the base substrate 20, and the thickness of the first oxide layer 225 is smaller than the thickness of the oxide layer of the first shielded gate trench transistor 21.

Step S31: forming a gate electrode that fills and covers a portion of the groove 224 at a position inside the groove 224 corresponding to the first oxide layer 225.

Step S32: forming the body region 222 on the side of the first oxide layer 225 close to the base substrate 20, and forming the first source region 223 on the side of the body region 222 close to the first oxide layer 225.

Step S33: forming the interlayer dielectric layer 228 and the first metal layer 227 in sequence on the side of the first oxide layer 225 facing away from the base substrate 20.

Wherein, the first metal layer 227 is respectively connected to the gate electrode 226, the first source region 223, the body region 222, and the source region of the first shielded gate trench transistor 21.

The manufacturing process of the first shielded gate trench transistor is basically the same as the manufacturing process of the exemplary shielded gate trench semiconductor device. Therefore, the manufacturing process of the first shielded gate trench transistor will not be described in detail in this example.

In some embodiments of the present invention, the epitaxial layer of the first shielded gate trench transistor 21 and the epitaxial layer 221 of the second shielded gate trench transistor 22 can be formed simultaneously or separately, and are not specifically limited here.

In some embodiments of the present invention, the second metal layer 211 and the third metal layer 212 of the first shielded gate trench transistor 21 and the first metal layer 227 of the second shielded gate trench transistor 22 can be formed simultaneously or separately, and are not specifically limited here.

In some embodiments of the present invention, as shown in FIG. 3B, forming the first oxide layer 225 during Step S30 may include Steps S301-S307.

Step S301: forming the epitaxial layer 221 on a side of the base substrate 20.

Step S302: forming the groove 224 extending in a direction close to the base substrate 20 in the epitaxial layer 221.

Step S303: forming a third oxide layer in the portion of the groove 224 close to the base substrate 20.

Step S304: forming a first groove on the side of the third oxide layer facing away from the base substrate 20, and depositing polycrystalline silicon in the first groove to form the field plate 229.

Step S305: forming a second oxide layer 225a covering the sidewalls of the groove 224, the third oxide layer and the field plate 229 in the groove 224, and on the side of the epitaxial layer 221 facing away from the base substrate 20.

Step S306: removing the second oxide layer 225a on the side of the epitaxial layer 221 facing away from the base substrate 20 and the second oxide layer 225a on the portion of the groove 224 facing away from the base substrate 20 through a photolithography process and an etching process.

Step S307: at the position where the second oxide layer 225a is removed from the epitaxial layer 221 and sidewalls of the groove 224, forming the first oxide layer 225 through a deposition process.

Wherein, the thickness of the first oxide layer 225 is 50 angstroms ± 10 angstroms.

In order to simplify the manufacturing process of the shielded gate trench semiconductor device, part of the manufacturing processes of the first shielded gate trench transistor 21 and the second shielded gate trench transistor 22 can be performed simultaneously. In the embodiment of the present invention, the above Steps S301 to S305 are performed simultaneously with the process of preparing the oxide layer of the first shielded gate trench transistor 21. The thickness of the second oxide layer 225a is the same as the thickness of the oxide layer of the first shielded gate trench transistor 21. For example, the thickness of the second oxide layer 225a may be 650A, 660A, 670A, 680A, 690A, 700A, 710A, 720A, 730A or 740A, etc.

The thickness of the first oxide layer 225 is smaller than thickness of the second oxide layer 225a, and the thickness of the first oxide layer 225 may be 45A, 46A, 47A, 48A, 49A, 50A, 51A, 52A, 53A or 54A, etc.

In some embodiments of the present invention, in Step S32 as shown in FIG. 3A, forming a first source region on a side of the body region close to the first oxide layer may include forming a second source region on a side of the body region close to the first oxide layer and forming a first source region based on the second source region. The concentration of the first source region is greater than the concentration of the source region of the first shielded gate trench transistor.

The first source region formed by secondary ion implantation can reduce the turn-on voltage of the second shielded gate trench transistor 22, thereby reducing the turn-on voltage of the entire shielded gate trench semiconductor device in advance and reducing power consumption.

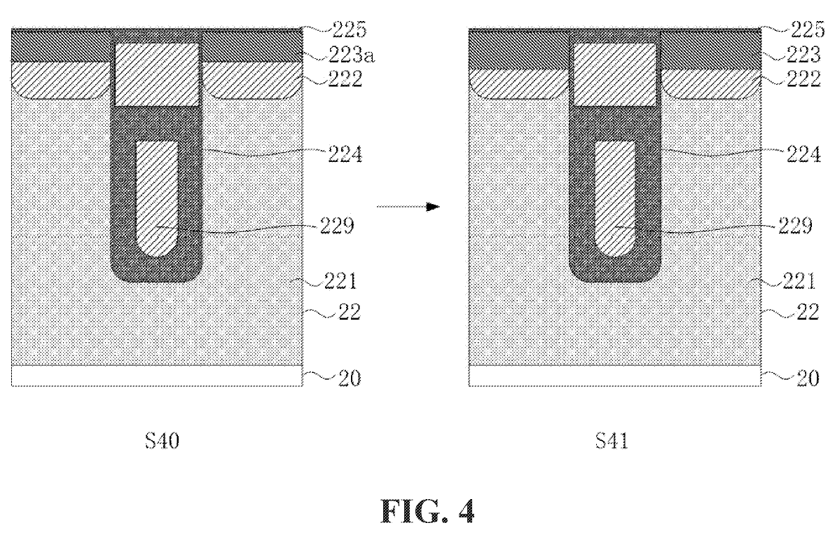

In some embodiments of the present invention, as shown in FIG. 4, forming a second source region on the side of the body region close to the first oxide layer and forming the first source region based on the second source region may include the followings steps.

Step S40: forming the second source region 223A on the side of the body region 222 close to the first oxide layer 225 through a photolithography process and an ion implantation process.

In some examples, the thickness of the photoresist in the photolithography process can be controlled to be within the range of (0.6±0.06) µm, and As is selected. The depth range is (300~500) A through the ion implantation process, the doping concentration range is 8E15±5%, and the doping type is N-type second source region.

Step S41: through the photolithography process, the ion implantation process and the tempering process, forming the first source region 223 based on the second source region 223A.

In some examples, the thickness of the photoresist in the photolithography process can be controlled within the range of (0.6±0.06) µm, and As is selected. The depth range is (400~600) A through the ion implantation process, the doping concentration range is 8E15±5%, and the doping type is the first source region of N type.

In some embodiments of the present invention, forming the body region on the side of the epitaxial layer facing away from the base substrate may include: forming the body region on the side of the epitaxial layer facing away from the base substrate through an ion implantation and tempering process.

Specifically, choose boron (B) and use the ion implantation process to form a body region with a depth within the range of (2700±800) A, a doping concentration of 9E12±5%, and a P-type doping type. The formed body region is tempered, and the tempering temperature is controlled at (950±50)°C.

The above are exemplary embodiments disclosed by the present invention, but it should be noted that various changes and modifications can be made without departing from the scope of the disclosed embodiments of the present invention defined by the claims. The functions, steps and/or actions of the method claims in accordance with the disclosed embodiments described herein need not be performed in any particular order. The embodiment numbers disclosed in the above embodiments of the present invention are only for description and do not represent the advantages or disadvantages of the embodiments. In addition, although the elements disclosed in the embodiments of the present invention may be described or claimed in individual form, they may also be understood as plural unless expressly limited to the singular.

It will be understood that, as used herein, the singular form “a” or “an” is intended to include the plural form as well, unless the context clearly supports an exception. It will also be understood that “and/or” as used herein is meant to include any and all possible combinations of one or more of the associated listed items.

Those of ordinary skill in the art should understand that the above discussion of any embodiments is only illustrative, and is not intended to imply that the disclosed scope of the embodiments of the present invention (including the claims) is limited to these examples; under the idea of the embodiments of the present invention, the above embodiments or technical features in different embodiments can also be combined, and there are many other changes in different aspects of the above embodiments of the present invention. For the sake of simplicity, they are not provided in the details. Therefore, any omissions, modifications, equivalent substitutions, improvements, etc. made within the spirit and principles of the embodiments of the present invention shall be included in the protection scope of the embodiments of the present invention.

Without further elaboration, it is believed that one skilled in the art can, using the preceding description, utilize the present invention to its fullest extent. The preceding preferred specific embodiments are, therefore, to be construed as merely illustrative, and not limitative of the remainder of the disclosure in any way whatsoever.

In the foregoing and in the examples, all temperatures are set forth uncorrected in degrees Celsius and, all parts and percentages are by weight, unless otherwise indicated.

The entire disclosures of all applications, patents and publications, cited herein and of corresponding Chinese Patent application No. 202510171683.5, filed February 17, 2025, are incorporated by reference herein.

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

What is claimed is:

1. A shielded gate trench semiconductor device, comprising:
a base substrate, and a first shielded gate trench transistor and a second shielded gate trench transistor formed thereon,
wherein, the second shielded gate trench transistor includes:
an epitaxial layer disposed on a side of the base substrate;
a body region disposed on a side of the epitaxial layer facing away from the base substrate;
a first source region disposed on a side of the body region facing away from the base substrate;
a groove that penetrates the first source region and the body region, and extends into an inside of the epitaxial layer;
a first oxide layer disposed on a sidewall of the groove and on a side of the first source region facing away from the base substrate, wherein a thickness of the first oxide layer is less than a thickness of an oxide layer of the first shielded gate trench transistor;
a gate electrode disposed to correspond to the first oxide layer and fills a portion of the groove; and
a first metal layer formed on the side of the first source region facing away from the base substrate, wherein the first metal layer is connected to the gate electrode, the first source region, the body region, and a source region of the first shielded gate trench transistor, respectively.

2. The shielded gate trench semiconductor device of claim 1, wherein a concentration of the first source region is greater than a concentration of the source region of the first shielded gate trench transistor.

3. The shielded gate trench semiconductor device of claim 1, wherein the thickness of the first oxide layer is 50 angstroms ± 10 angstroms.

4. The shielded gate trench semiconductor device of claim 1, wherein a doping type of the first source region is of a first doping type, a doping type of the body region is of a second doping type, and a doping concentration of the body region is less than a doping concentration of the first source region.

5. The shielded gate trench semiconductor device of claim 1, wherein the first metal layer is used to apply a first voltage to the gate electrode, the first source region, and the body region of the second shielded gate trench transistor and the source region of the first shielded gate trench transistor.

6. The shielded gate trench semiconductor device of claim 5, wherein the first shielded gate trench transistor includes:
a second metal layer connected to a gate electrode of the first shielded gate trench transistor, wherein the second metal layer is used to apply a second voltage to the gate electrode of the first shielded gate trench transistor; and
a third metal layer connected to the source region and a body region of the first shielded gate trench transistor, wherein the third metal layer is used to apply a third voltage to the source region and the body region of the first shielded gate trench transistor.

7. A manufacturing method of a shielded gate trench semiconductor device, the manufacturing method comprising:
forming a first shielded gate trench transistor and a second shielded gate trench transistor on a base substrate, wherein the formation of the second shielded gate trench transistor includes:
forming an epitaxial layer on a side of the base substrate;
forming a groove in the epitaxial layer, wherein the groove extends from a side of the epitaxial layer facing away from the base substrate towards a direction closer to the base substrate;
forming a first oxide layer on a sidewall of the groove and on the side of the epitaxial layer facing away from the base substrate, wherein a thickness of the first oxide layer is less than a thickness of an oxide layer of the first shielded gate trench transistor;
forming a gate electrode that fills and covers a portion of the groove at a position corresponding to the first oxide layer;
forming a body region on a side of the first oxide layer closer to the base substrate;
forming a first source region on a side of the body region closer to the first oxide layer;
forming a first metal layer on a side of the first oxide layer facing away from the base substrate, wherein the first metal layer is connected to the gate electrode, the first source region, the body region, and a source region of the first shielded gate trench transistor, respectively.

8. The manufacturing method of claim 7, wherein the formation of the first source region on the side of the body region closer to the first oxide layer includes:
forming a second source region on the side of the body region closer to the first oxide layer and forming the first source region based on the second source region, wherein a concentration of the first source region is greater than a concentration of the source region of the first shielded gate trench transistor.

9. The manufacturing method of claim 8, wherein the formation of the second source region on the side of the body region closer to the first oxide layer and the formation of the first source region based on the second source region includes:
forming the second source region on the side of the body region closer to the first oxide layer through photolithography and ion implantation processes; and
forming the first source region based on the second source region through photolithography, ion implantation, and annealing processes.

10. The manufacturing method of claim 7, wherein the formation of the first oxide layer on the sidewall of the groove and on the side of the epitaxial layer facing away from the base substrate includes:
forming a second oxide layer inside the groove and on the side of the epitaxial layer facing away from the base substrate;
removing the second oxide layer on the side of the epitaxial layer facing away from the base substrate and the second oxide layer on the sidewall of the groove facing away from the base substrate through photolithography and etching processes; and
forming the first oxide layer at positions where the second oxide layer has been removed from the epitaxial layer and the sidewall of the groove, wherein a thickness of the first oxide layer is 50 angstroms ± 10 angstroms.
